(19) United States
(12) Patent Application Publication
(10) Pub. No.: US 2017/0243851 A1
(43) Pub. Date: Aug. 24, 2017

(54) APPARATUS FOR ESPECIALLY THERMALLY JOINING MICRO-ELECTROMECHANICAL PARTS

(71) Applicant: ATV TECHNOLOGIE GMBH, Vaterstetten (DE)

(72) Inventors: Ventzeslav RANGELOV, Vaterstetten (DE); Siegfried KOWALSKY, Vaterstetten (DE); Walter PORT, Vaterstetten (DE); Roland KOCH, Vaterstetten (DE)

(73) Assignee: ATV TECHNOLOGIE GMBH, Vaterstetten (DE)

(21) Appl. No.: 15/503,929

(22) PCT Filed: Aug. 14, 2015
(86) PCT No.: PCT/DE2015/000401

§ 371 Date: May 8, 2017

(30) Foreign Application Priority Data
Aug. 14, 2014 (DE) 10 2014 111 634.8

(51) Int. Cl. H01L 23/00; B23K 20/02; B23K 1/00; B23K 3/04; B23K 3/08

(52) U.S. Cl. CPC H01L 24/75; H01L 24/95; H01L 24/83; B23K 3/04; B23K 3/087; B23K 1/0016; B23K 20/023; H01L 2224/75102; H01L 2224/75283; H01L 2224/75252; H01L 2224/75251; H01L 2224/7555; H01L 2224/75315; H01L 2224/7598; H01L 2224/83065; H01L 2224/83203; H01L 2224/83209; H01L 2224/8323; H01L 2224/83825; H01L 2224/8384; H01L 2224/95093; B23K 2201/40

(57) ABSTRACT

The invention relates to an apparatus for especially thermally joining micro-electromechanical parts (2, 3) in a process chamber (8), comprising a bottom support plate (11) for holding at least one first (2) of the parts (2, 3) to be joined, and a pressing device (15) for applying pressure to at least one second (3) of the parts (2, 3) to be joined in relation to the at least one first part (2). The pressing device (15) is equipped with an expandable membrane (19) provided for entering in contact with the at least one second part (3). Fluid pressure, in particular gas pressure, can be applied to said membrane (19) on the side thereof facing away from the parts (2, 3) to be joined.

### FIELD OF THE INVENTION

The invention relates to an apparatus for especially thermally joining micro-electromechanical parts, comprising a pressing device for pressing the parts to be joined against each other.

### STATE OF THE ART

In semiconductor technology, different methods are used to attach micro-electromechanical parts, such as, e.g., chips or dies, respectively, wafers, LEDs, etc., or assemblies consisting thereof, to a carrier.

In this connection, the mounting technology for power modules has to meet ever-increasing requirements with respect to switching speeds, conduction losses and switching losses and temperature resistance, not only because of the continuing further development of semiconductors made of silicon or the frequently used semiconductor materials silicon carbide (SiC) and gallium nitride (GaN), respectively, but also because of new fields of application and complex topographies.

Power semiconductors are usually applied onto a carrier substrate with structured copper or aluminum. The substrate may be an IMS (insulated metal substrate), or use is made of substrates with an inner ceramic layer of aluminum oxide or aluminum nitride, which are referred to as DCB (direct copper bond), DAB (direct aluminum bond) or AMB (active metal brazing) substrates. A planar chip connection is formed in these cases, usually by soldering.

For highly stressable connections, more recent joining techniques, such as Ag sintering or diffusion soldering, also known as TLPB (transient liquid phase bonding) or TLPS (transient liquid phase soldering), are used.

All these known joining methods require the application of pressure onto the parts to be joined, which pressure has to be maintained during the joining operation for a predefined time, depending on the process, e.g. 30 MPa for several seconds in Ag sintering.

In apparatuses known from practice, which usually comprise a vacuum chamber with a heating plate as the support for the parts to be joined and a vertically displaceable press or bonder head, pressure is applied via the bonder head with a planar press plate. For practical purposes, in order to enable approximately uniform contacting for different chip heights, silicone mats are used on the bonder head or the press plate, respectively, to apply the operating pressure onto the semiconductor structures during joining.

Disadvantageously, even relatively soft silicone mats do not guarantee uniform pressure distribution on components differing in height. Only the highest or the higher chips, respectively, can be pressed accordingly, while the lower chips are not subjected to the required contact pressure. The same applies to uneven chips, which are pressed sufficiently over a partial area. Thus, even using a press plate with a silicone mat, the joining quality is problematic for high-resistance connections.

For high-resistance connections of semiconductor components differing in height, a single-chip connection may be selected, which, however, results in a long overall processing time and correspondingly high costs.

### DISCLOSURE OF THE INVENTION

### Technical Problem

Therefore, it is an object of the present invention to provide an apparatus for especially thermally joining micro-electromechanical parts, wherein uniform pressure application of a pressing device onto the parts to be joined is ensured even for different approach distances of the pressing device with respect to the parts, thus ensuring a reproducible, high joining quality even for a plurality of different components to be joined at the same time.

### Technical Solution

The above object is achieved by an apparatus for especially thermally joining micro-electromechanical components, said apparatus comprising a process chamber with a lower support plate for receiving at least one first component of the components to be joined and with a pressing device for applying pressure onto at least one second component of the components to be joined, in direction of the least one first component. According to the invention, the pressing device is formed with an expandable membrane provided for contacting the at least one second component, wherein fluid pressure, in particular gas pressure, can be applied onto said membrane on its side facing away from the components to be joined.

### Advantageous Effects

The apparatus of the invention has the advantage of allowing several micro-electromechanical components differing in geometry and height to be joined simultaneously to a carrier with a high joining quality. The pressure applied onto the components, in particular chips, by the expandable membrane is the same for all chips to be pressed, because the membrane adapts to the target surface, i.e. to the topography of the components to be pressed, due to the expansion of the membrane according to the fluid pressure, so that the fluid pressure of the pressing device acts uniformly on all chips.

Advantageously, the isostatic pressing of semiconductor components of different shapes also allows a plurality of such semiconductor components to be processed in a joining step using joining methods for producing highly stressable connections by means of thermocompression bonding, such as Ag sintering or planar diffusion soldering in accordance with the TLPB (transient liquid phase bonding) process or the TLPS (transient liquid phase soldering) process.

Due to the membrane allowing a plurality of different semiconductor components to be joined at the same time by isostatic pressing, said components can be positioned exactly in their final positions, in contrast to single-chip methods, for example, and advantageously processed in a sealed atmosphere, in particular oxygen-free, with a high purity of the atmosphere.

The pressing device with the membrane expandable by fluid pressure has been shown to be universally applicable both with regard to joining methods, i.e. from conventional planar soldering to diffusion soldering and to sinter technologies, as well as with regard to the parts to be joined, such as chips, for example, whose surface may be highly sensitive with respect to substrates or wafers, respectively, wafers among each other, LEDs on chip carriers etc., and their different geometries.

The pressing device according to the invention further has the advantage that potential skewing of a contact plate or of a bonder head with respect to a support plate carrying the components to be joined can be compensated for by the membrane which adapts to the respective target surface under fluid pressure.

Moreover, during soldering or diffusion soldering, e.g. in a TLPS process, the flexibility of the membrane allows the selection of different thicknesses of the soldering material because differences in height are generally compensated for by the membrane.

The pressure application by the expandable membrane has the additional advantage that adapting the membrane to the target surface affects neither the positioning accuracy of the parts to be contacted nor their surface sensitivity.

The fluid from a suitable fluid medium source which the pressing device applies to the flexible membrane is preferably a gas, which may be compressed air or any other gas which can be pressurized.

Depending on the fluid selected, it is also possible to use it for cooling or heating at the same time, in accordance with the joining technique used.

Generally, a liquid may be selected instead of a gas for applying pressure onto the flexible membrane, combined, in particular, with cooling. However, when using a liquid to apply pressure, accordingly high sealing requirements have to be met in order to prevent liquid leakage which may damage the components to be joined and/or the apparatus.

In an advantageous embodiment of the invention, the membrane is made of a gas-tight sheet material, in particular a rubberlike material. The material selection depends on the respective joining method, the temperatures it usually employs, the required contact pressure and the topography of the target surface. Gas-tight and highly tear-resistant sheet materials are commercially available in a multiplicity of thicknesses and material compositions, so that the pressing device according to the invention can be realized at low cost with standard materials.

The thickness of the membrane and its expansibility are preferably selected according to the topography of the components to be joined such that the membrane, in the contacting operating condition, applies at least approximately the same contact pressure onto the components, regardless of any differences in height existing between them.

In a particularly advantageous embodiment, the membrane may extend over a pressure plate, also referred to as bonder plate or die, which is arranged at least substantially plane-parallel to the support plate and displaceable at least perpendicular thereto, wherein a pressure medium can be supplied between the membrane and the pressure plate so that the membrane bulges towards the parts to be joined.

In this case, the membrane may be attached, in a secure and sealed manner, by its edge region to the pressure plate by means of a suitable holding and fixing device.

Usual constructions of bonder plates, provided, for example, as a massive plate with a central guide rod on a side facing away from the contact surface, thus require only minor modification in order to be embodied according to the invention. This allows pressure medium to be fed to the contact side of the pressure plate, and consequently to a membrane attached thereto, through at least one suitable bore in the pressure plate. The corresponding connection to a pressure medium source may be effected by a separate flexible tube and/or a through hole in the pressure plate or the guide rod, respectively.

The holding and fixing device may be realized by any known fixing method, with an easily releasable connection, such as e.g. a screw and/or clip connection, being advantageous in terms of the required replacement of the membrane due to wear or changing process requirements.

Since a sealing device is to be provided between the pressure plate and the membrane, it may be advantageous if the holding and fixing device comprises a clamping ring, which extends, in particular, around the circumference of the membrane and allows the membrane to be fixed to the pressure plate and/or an interposed sealing device.

In an advantageous embodiment, it may further be envisaged that a negative pressure can be applied onto the membrane on its side facing away from the components to be joined, in particular in the non-contacting operating condition of the membrane.

Aspiration of the membrane, for example to a pressure plate, in the non-contacting operating condition advantageously prevents the membrane from potentially sagging due to gravity, thereby touching the parts to be joined and adversely affecting their positioning accuracy. A heating device may be provided above the pressure plate and/or below the support plate in order to adjust the temperature required for the respective type of connection. Conveniently, the support plate itself is provided as a heating plate.

Using an upper heating device and a lower heating device, a two-zone heating can be established, wherein the heating devices may be provided as infrared (IR) radiator devices, which may comprise a field of parallel halogen tubes, for example.

Such an IR heating device has the advantage that it allows quick heating and all elements are kept at a uniform temperature, thereby ensuring high temperature homogeneity in the apparatus and, thus, qualitative equality of the connection of the components.

In order to enable joining processes for producing highly stressable connections, which usually require a closed system with a reducing atmosphere, it is advantageous if the process chamber is provided as a vacuum chamber with a sealed housing and at least one opening of the housing is provided for deaeration or evacuation and for aeration or introduction of gas, respectively, of the vacuum chamber.

To ensure optimal contact pressure in accordance with the selected process, in particular a TLP process or a TLPB process or a sintering process, an advantageous embodiment of the invention provides a control device by means of which at least the fluid pressure of the pressing device can be adjusted according to the selected process and to the topography of the components to be joined.

Further advantages and advantageous embodiments of an apparatus according to the invention are apparent from the description, the drawings and the claims.

### BRIEF DESCRIPTION OF THE DRAWINGS

An exemplary embodiment of an inventive apparatus for thermally joining semiconductor chips to a carrier is shown in the drawings in a schematically simplified manner and will be explained in more detail below.

In the drawings:

FIG. 1 shows a simplified three-dimensional front view of an apparatus for thermally joining semiconductor components, said apparatus comprising a vacuum chamber, and

FIG. 2 shows another three-dimensional view of the apparatus of FIG. 1 in longitudinal section.

### EMBODIMENTS OF THE INVENTION

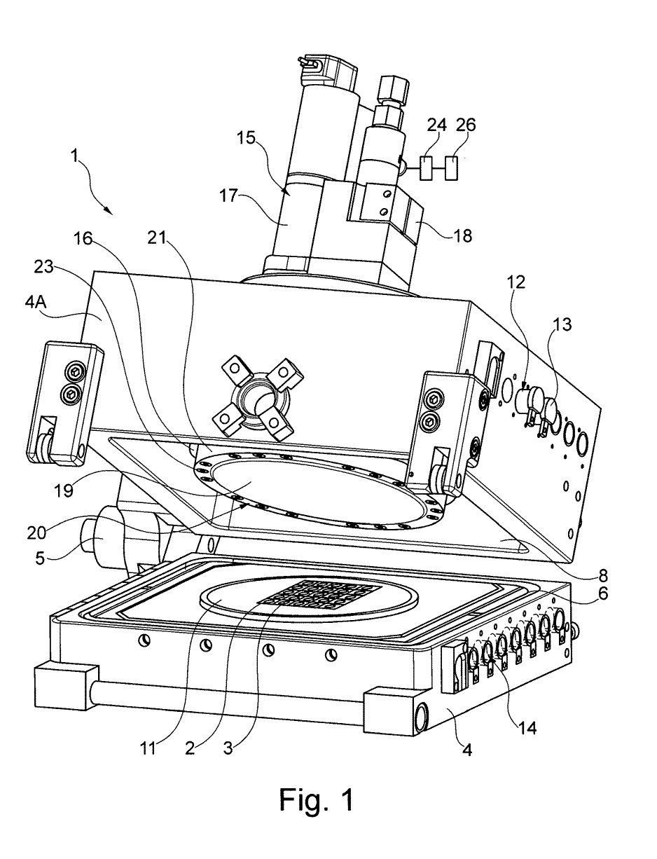

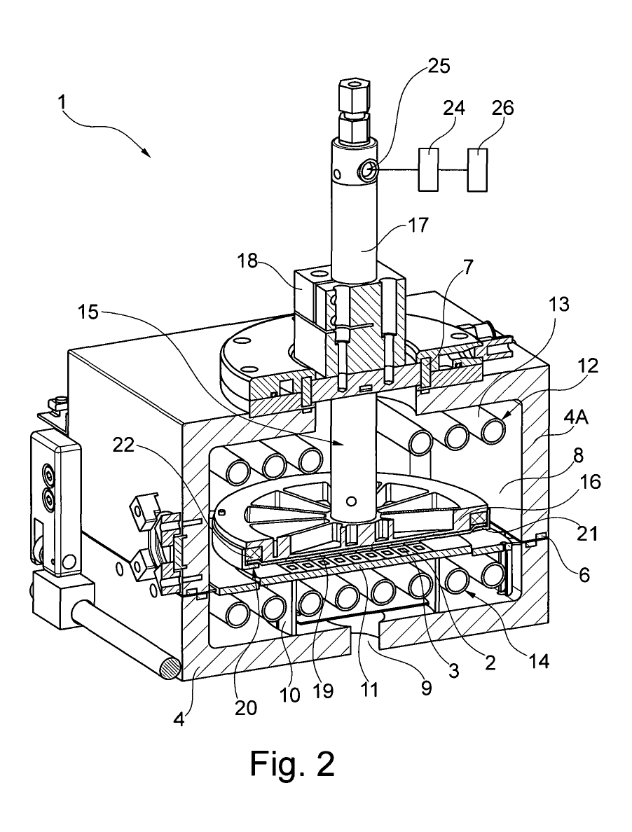

FIGS. 1 and 2 show an apparatus 1 for thermally joining first micro-electromechanical components 2 to second micro-electromechanical components 3, wherein said first components 2 are Si chips of different heights and said second components 3 are Cu carriers in this case.

The apparatus 1 comprises a two-part housing 4, which can be opened and closed by a swivel mechanism 5 and can be sealed to the environment by sealing devices 6, 7. A process chamber 8 formed within the housing 4 is presently embodied as a vacuum chamber with an opening 9 for deaeration or evacuation and aeration or introduction of gas, respectively, of the vacuum chamber.

In the process chamber, a support plate 11 for the first components 2 in the form of Cu carriers and for the Si chips arranged thereon as second components 3 is arranged on a support device 10. For the TLPS process used as the joining process in the illustrated embodiment, the support plate 11 is provided as a heating plate. Moreover, in order to adjust the required process temperature, an upper heating device 13 is arranged above the support plate 11 in a swiveling cover 4a of the housing 4, said upper heating device 13 being provided as an IR radiator device comprising a field of parallel halogen tubes 13.

Analogous to the upper heating device 12, a lower heating device 14 is provided below the support plate 11, said lower heating device 14 also being provided as an IR radiator device comprising a field of parallel halogen tubes, thus allowing two-zone temperature adjustment with optimal temperature distribution during the joining process.

A pressing device 15 is provided for pressing the chips 3 onto the Cu carrier 2, said pressing device 15 comprising a metallic pressure plate or bonder plate 16, respectively, which is arranged plane-parallel to the support plate 11 and is connected, on its side facing away from the contact pressure side, to a guide rod 17. The guide rod 17 extends out of the housing 4 in a vacuum-sealed manner and is movable by means of a motor 18 in a direction perpendicular to the plane of the support plate 11, i.e. vertically in the present case, and thus towards the components 2, 3 and away from them. A pressure medium duct 25, not shown in detail, is formed inside the guide rod 17. The pressure medium duct 25 is connected to a pressure medium source 26, shown only symbolically, and extends through the pressure plate 16 as far as to the components 2, 3 and, thus, as far as to the side of the pressure plate 16 facing the target surface.

An expandable membrane 19 is arranged on this contact pressure side of the pressure plate 16, which membrane 19 is made of a gas-tight, elastic sheet material and is designed, in the present case, to be subjected to compressed air as the pressure medium.

In the embodiment shown, the membrane extends up to the circumference of the pressure plate 16, which is circular here, and is attached to the edge region of the pressure plate 16 by means of a holding and fixing device 20, the latter comprising a clamping ring 21, which extends around the circumference of the membrane 19. The clamping ring 21 is connected to a sealing ring 22 forming the sealing device between the membrane and a flange-like step on the edge of the pressure plate 16, and is also connected to the pressure plate 16 itself.

As the connecting means of the holding and fixing device 20, screw connections 23 are provided, which are distributed over the circumference of the clamping ring 21 and of the pressure plate 16.

A control device 24 is provided to adjust at least the fluid pressure of the pressing device 15 according to the predefined process parameters and the topography of the components 2, 3 to be joined, said control device 24 directing compressed air from the pressure medium source 18 into the area between the contact surface of the pressure plate 16 and the membrane 19. This causes the membrane 19 to expand towards the chips 3 forming the target surface and to contact them such that an isostatic contact pressure is applied to all chips 3, which presently have different geometries and different heights.

In addition to the pressure applied via the pressure medium duct 25, the membrane 19 may be aspirated in the non-contacting state so that it is in planar contact, in this state, with the pressure plate 16 and does not bulge towards the components 2, 3 to be joined, therefore not being able to have a negative effect on them.

The depicted apparatus 1 is universally applicable and can be used not only for the TLPS process described herein, but also for other soldering and diffusion soldering processes as well as sintering processes. Depending on the joining process selected, only the process parameters, such as temperature, atmosphere and, as the case may be, the material and thickness of the exchangeable membrane will change.

1. An apparatus for especially thermally joining micro-electromechanical components (2, 3) in a process chamber (B) with a lower support plate (11) for receiving at least one first component (2) of the components (2, 3) to be joined and with a pressing device (15) for applying pressure onto at least one second component (3) of the components (2, 3) to be joined, in direction of the least one first component (2), characterized in that said pressing device (15) is formed with an expandable membrane (19) provided for contacting the at least one second component (3), wherein fluid pressure, in particular gas pressure, can be applied onto said membrane (19) on its side facing away from the components (2, 3) to be joined.

2. The apparatus according to claim 1, characterized in that the membrane (19) is made of a gas-tight sheet material, in particular a rubberlike material.

3. The apparatus according to claim 1 or 2, characterized in that the thickness of the membrane (19) and its expansibility are preferably selected according to the topography of the components (2, 3) to be joined such that the membrane (19), in the contacting operating condition, applies at least approximately the same contact pressure onto the components (2, 3), regardless of any differences in height existing between them.

4. The apparatus according to any one of claims 1 to 3, characterized in that the membrane (19) extends over a pressure plate (16), which is arranged at least substantially plane-parallel to the support plate (11) and displaceable at least perpendicular thereto, wherein a pressure medium can be supplied between the membrane (19) and the pressure plate (16) so that the membrane (19) bulges towards the components (2, 3) to be joined.

5. The apparatus according to any one of claims 1 to 4, characterized in that the membrane (19) is attached, in a secure and sealed manner, by its edge region to the pressure plate (16) by means of a holding and fixing device (20).

6. The apparatus according to any one of claims 1 to 5, characterized in that the holding and fixing device (20) comprises a clamping ring (21), which extends, in particular, around the circumference of the membrane (19) and allows the membrane (19) to be fixed to the pressure plate (16) and/or to an interposed sealing device (22).

7. The apparatus according to any one of claims 1 to 6, characterized in that a negative pressure can be applied onto the membrane (19) on its side facing away from the components (2, 3) to be joined, in particular in the non-contacting operating condition of the membrane (19).

8. The apparatus according to any one of claims 1 to 7, characterized in that a heating device (12, 14) is provided above the pressure plate (16) and/or below the support plate (11).

9. The apparatus according to any one of claims 1 to 8, characterized in that the support plate (11) is provided as a heating plate.

10. The apparatus according to any one of claims 1 to 9, characterized in that the process chamber is provided as a vacuum chamber (8) with a sealed housing (4) and with at least one opening (9) of the housing (4) that is provided for deaeration/evacuation and aeration/gasifying of the vacuum chamber (8).

11. The apparatus according to any one of claims 1 to 10, characterized in that by means of a control device (24) at least the fluid pressure of the pressing device (15) can be adjusted according to the selected process, in particular a TLPS (transient liquid phase soldering) process or a TLPB (transient liquid phase bonding) process or a sintering process, and according to the topography of the components (2, 3) to be joined.
